(19) United States
(12) Patent Application Publication
(10) Pub. No.: US 2026/0107790 A1
(43) Pub. Date: Apr. 16, 2026

(54) FAN-OUT WAFER LEVEL PACKAGING UNIT AND PACKAGE FORMED BY STACKING THE SAME

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/336,509

(22) Filed: Sep. 23, 2025

(30) Foreign Application Priority Data
Oct. 16, 2024 (TW) 113139361

(51) Int. Cl. H01L 23/00; H01L 25/11

(52) U.S. Cl. CPC H10W 70/60; H10W 90/00; H10W 70/655; H10W 90/22

(57) ABSTRACT

A fan-out wafer level packaging (FOWLP) unit and a package formed by stacking the same are provided. The FOWLP unit includes a substrate, at least one die, a first dielectric layer, at least one second conductive pillar, a second dielectric layer, a plurality of first conductive circuits, a third dielectric layer, and a plurality of metal protective layers. The first conductive circuits are produced on a second surface of the die by filling a metal paste into slots and grinding the metal paste. A layout of second bonding pads on a first surface of the FOWLP unit and a layout of first bonding pads on a second surface of the FOWLP unit are the same and this is beneficial to mass-production of the FOWLP units.

### CROSS-REFERENCE TO RELATED APPLICATIONS

This non-provisional application claims priority under 35 U.S.C. § 119(a) on Patent Application No(s). 113139361 filed in Taiwan, R.O.C. on Oct. 16, 2024, the entire contents of which are hereby incorporated by reference.

### BACKGROUND OF THE INVENTION

The present invention relates to a package, especially to a fan-out wafer level packaging (FOWLP) unit and a package formed by stacking the same.

In the advanced packaging process such as FOWLP, a redistribution layer (RDL) is the most critical because respective conductive circuits in the RDL make a plurality of die pads on dies have electrical extension in the XY plane and interconnections. Thus a plurality of bonding pads is arranged around the die in a more distributed manner. Thereby design, space, and reliability of the respective conductive circuits are effectively improved. Yet how to keep balance between the electrical extension in the XY plane and interconnections of the conductive circuits and the compact design to a certain degree, the most critical point is the manufacturing of the respective conductive circuits in the RDL.

However, the formation of the respective conductive circuits in the RDL of the FOWLP technology available now is by chemical plating or electroplating. Thus not only cost for material and manufacturing is high, the manufacturing process is also not environmental friendly.

How to allow the FOWLP units getting easier to form stacked package and become be mass-producible when the FOWLP units are stacked to form a package for higher efficiency or computing power.

### SUMMARY OF THE INVENTION

Therefore, it is a primary object of the present invention to provide a a fan-out wafer level packaging (FOWLP) unit and a package formed by stacking the same. The FOWLP unit includes a substrate, at least one die, a first dielectric layer, at least one second conductive pillar, a second dielectric layer, a plurality of first conductive circuits, a third dielectric layer, and a plurality of metal protective layers. The first conductive circuits are produced on a second surface of the die by filling a metal paste into slots and grinding the metal paste. Thereby problems of the FOWLP module available now generated during manufacturing of the respective conductive circuits including higher manufacturing cost and less environmental benefit can be solved. A layout of second bonding pads on a first surface of the FOWLP unit and a layout of first bonding pads on a second surface of the FOWLP unit are the same and this helps stacked package and mass production of the FOWLP units at the manufacturer's end.

In order to achieve the above object, a FOWLP unit according to the present invention is provided. The FOWLP unit includes a substrate, at least one die, a first dielectric layer, at least one second conductive pillar, a second dielectric layer, a plurality of first conductive circuits, a third dielectric layer, and a plurality of metal protective layers. The substrate consists of a first surface, a second surface opposite to the first surface, and a plurality of first conductive pillars penetrating the first surface and the second surface. The die is cut from a wafer and provided with a first surface and a second surface opposite to the first surface. The first surface is fixed on the second surface of the substrate and a plurality of die pads is disposed on the second surface. A range perpendicular to the second surface of the die is defined as a die area. The first dielectric layer is arranged at the second surface of the substrate and covering the die. The first dielectric layer is provided with at least one insertion hole which is connected to the first conductive pillar correspondingly. The second conductive pillar is formed in each of the insertion holes to be electrically connected to the corresponding first conductive pillar and exposed through the insertion hole. The second dielectric layer is disposed over the first dielectric layer and having at least one slot which is extending in a horizontal direction and connected to the corresponding second conductive pillar. The respective first conductive circuits are formed by a metal paste filled into the respective slots correspondingly and electrically connected to the second conductive pillars. The third dielectric layer is disposed over the second dielectric layer and the first conductive circuits. The third dielectric layer is provided with at least one opening. The respective first conductive circuits are exposed through the respective first openings and forming a first bonding pad in each of the first openings. The metal protective layers are formed in the first openings correspondingly and electrically connected to the respective first conductive circuits. Each of the first conductive pillars is exposed on the first surface of the substrate and forming a second bonding pad on the first surface of the substrate. The die is electrically connected to the outside through the die pads of the die, the first conductive circuits, the second conductive pillars, the first conductive pillars, and the second bonding pads located at the substrate in turn. The die is electrically connected to the outside through the die pads of the die, the first conductive circuits, the metal protective layers, and the first bonding pads around the die area on the second surface of the die in turn. Thereby the FOWLP unit is formed. The FOWLP unit further includes a first surface and a second surface. The respective second bonding pads of the substrate in the FOWLP unit are located on the first surface of the FOWLP unit. The first bonding pads in the first openings of the FOWLP unit are located at the second surface of the FOWLP unit. The second bonding pads on the first surface of the FOWLP unit and the first bonding pads on the second surface of the FOWLP unit have the same arrangement (layout). A method of manufacturing the FOWLP unit includes the following steps. Step S1: providing a substrate having a first surface, a second surface opposite to the first surface, and a plurality of first conductive pillars penetrating the first surface and the second surface. The first conductive pillars are exposed on the first surface of the substrate to form second bonding pads on the first surface of the substrate. Step S2: arranging a plurality of dies cut from at least one wafer at the substrate with an interval between the two adjacent dies. Each of the dies is provided with a first surface fixed on the second surface of the substrate, a second surface opposite to the first surface, and a plurality of die pads disposed on the second surface of the die. A range perpendicular to the second surface of the die is defined as a die area. Step S3: paving a first dielectric layer over the second surface of the substrate and the dies and the first dielectric layer covering the respective dies. Then forming a plurality of insertion holes on the first dielectric layer and penetrating the first dielectric layer. Later forming a second conductive pillar in each of the insertion holes. Step S4: producing a plurality of first conductive circuits on the second surface of the die by filling a metal paste into slots and grinding the metal paste. First paving a second dielectric layer over the second surface of the substrate. Then forming a plurality of slots horizontally on the first dielectric layer and exposing the second conductive pillars through the slots. Next filling a metal paste into the slots and allowing a level of the metal paste higher than a surface of the second dielectric layer. Lastly grinding the metal paste with the level higher than a surface of the second dielectric layer to make a surface of the metal paste flush with the surface of the second dielectric layer and form a plurality of the first conductive circuits. Step S5: paving a third dielectric layer over the second dielectric layer and forming a plurality of openings horizontally on the third dielectric layer so that the first conductive circuits are exposed through the first openings. Lastly forming a metal protective layer in the respective first openings. Each of the first conductive circuits forms a first bonding pad in each of the first openings. The metal protective layers are electrically connected to the first conductive circuits correspondingly. Step S6: performing cutting to form a plurality of FOWLP units.

Preferably, a fourth dielectric layer and a plurality of second conductive circuits are disposed on the first surface of the substrate by the RDL process. The fourth dielectric layer is provided with at least one second opening extending in a horizontal direction. The second conductive circuits are formed by a metal paste filled in the respective second openings and electrically connected with the second bonding pads. A method of manufacturing the second conductive circuits includes the following steps. Step S1: first paving a fourth dielectric layer on the first surface of the substrate; then forming a plurality of second openings horizontally on the fourth dielectric layer and allowing the second bonding pads to be exposed through the second openings. Step S2: filling a metal paste into the respective second openings and allowing a level of the metal paste higher than a surface of the fourth dielectric layer. Step S3: grinding the metal paste with the level higher than the surface of the fourth dielectric layer to make a surface of the metal paste flush with the surface of the fourth dielectric layer and form a plurality of second conductive circuits.

Preferably, each of the second conductive circuits is provided with a solder ball which is electrically connected to the first bonding pad through the second conductive circuit.

Preferably, the substrate includes, but not limited to, a silicon substrate, a glass substrate, and a ceramic substrate. The metal pastes used to produce the first and the second conductive circuits include silver paste, nano-scale silver paste, copper paste, and nano-scale copper paste.

Preferably, a thickness of the FOWLP unit is 200 micrometers (um).

Preferably, the first surface of the die is arranged at the substrate by a die attach film (DAF).

Preferably, a package formed by stacking of a plurality of the FOWLP units is provided. The package includes at least two FOWLP units and at least one connecting circuit. The FOWLP units are stacked vertically such as one at an upper position and another one at a lower position correspondingly. The second bonding pads of one of the FOWLP units at the upper position are corresponding to the first bonding pads of one of the FOWLP units at the lower position in a one-to-one manner. The connecting circuit is arranged between the second bonding pads of one of the FOWLP units at the upper position and the first bonding pads of one of the FOWLP units at the lower position to form an electrical connection.

Preferably, the dies of one of the FOWLP units at the upper position and the dies of one of the FOWLP units at the lower position can have the same or different specifications and functions.

Preferably, the connecting circuit is a solder ball.

### BRIEF DESCRIPTION OF THE DRAWINGS

FIG. 1 is a side sectional view of a fan-out wafer-level packaging (FOWLP) unit of an embodiment in use according to the present invention;

FIG. 2 is a side sectional view of a substrate of an embodiment according to the present invention;

FIG. 3 is a schematic drawing showing a die arranged at the substrate of the embodiment in FIG. 2 according to the present invention;

FIG. 4 is a schematic drawing showing a first dielectric layer disposed on the die of the embodiment in FIG. 3 according to the present invention;

FIG. 5 is a schematic drawing showing a second conductive pillar disposed on the first dielectric layer of the embodiment in FIG. 4 according to the present invention;

FIG. 6 is a schematic drawing showing a second dielectric layer disposed over the first dielectric layer of the embodiment in FIG. 5 according to the present invention;

FIG. 7 is a schematic drawing showing a metal paste filled into slots of the second dielectric layer of the embodiment in FIG. 6 according to the present invention;

FIG. 8 is a schematic drawing showing grinding of the metal paste at a level higher than a level of a surface of the second dielectric layer to form first conductive circuits of the embodiment in FIG. 7 according to the present invention;

FIG. 9 is a schematic drawing showing a third dielectric layer disposed over the second dielectric layer of the embodiment in FIG. 8 according to the present invention;

FIG. 10 is a schematic drawing showing metal protective layers mounted in openings of the third dielectric layer of the embodiment in FIG. 9 according to the present invention;

FIG. 11 is a side sectional view showing a fourth dielectric layer disposed on a packaging unit of an embodiment according to the present invention;

FIG. 12 is a schematic drawing showing a metal paste filled into slots of the fourth dielectric layer of the embodiment in FIG. 11 according to the present invention;

FIG. 13 is a schematic drawing showing grinding of the metal paste at a level higher than a level of a surface of the fourth dielectric layer to form second conductive circuits of the embodiment in FIG. 12 according to the present invention;

FIG. 14 is a schematic drawing showing a FOWLP unit of the embodiment in FIG. 13 rotated an angle according to the present invention;

FIG. 15 is a side sectional view showing an embodiment being packaged according to the present invention;

FIG. 16 is a side sectional view showing another embodiment being packaged according to the present invention.

### DETAILED DESCRIPTION OF THE PREFERRED EMBODIMENT

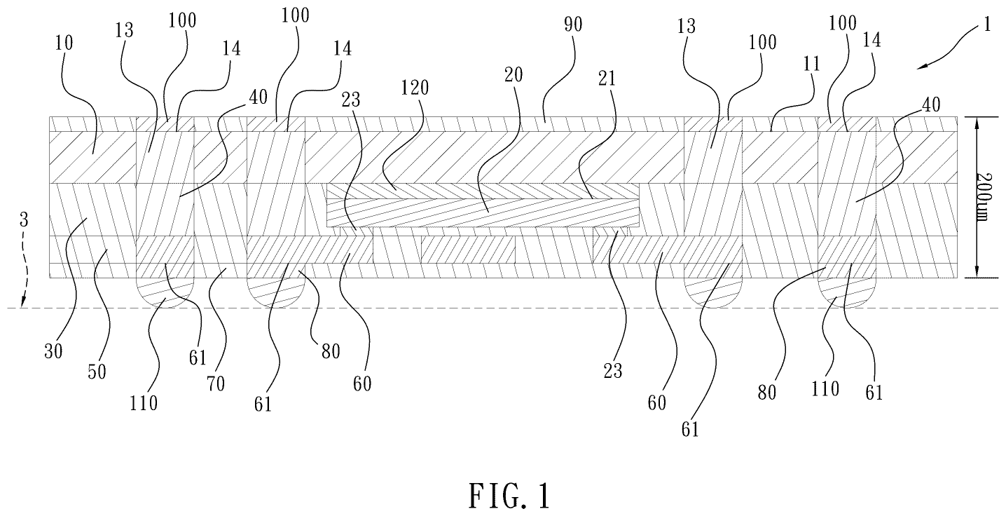

Refer to FIG. 1, a fan-out wafer-level packaging (FOWLP) unit 1 according to the present invention is provided. The FOWLP unit 1 includes a substrate 10, at least one die 20, a first dielectric layer 30, at least one second conductive pillar 40, a second dielectric layer 50, a plurality of first conductive circuits 60, a third dielectric layer 70, and a plurality of metal protective layers 80.

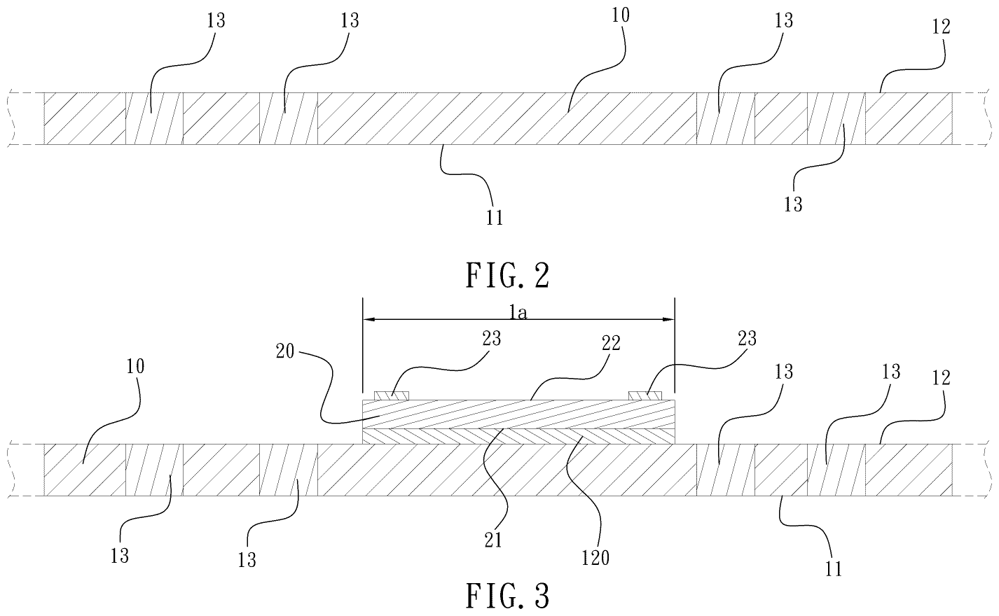

Refer to FIG. 2, the substrate 10 consists of a first surface 11, a second surface 12 opposite to the first surface 11, and a plurality of first conductive pillars 13 penetrating the first surface 11 and the second surface 12. After a plurality of insertion holes formed on the substrate 10 by means of Through Silicon ViA (TSV) process, the first conductive pillars 13 are mounted into the insertion holes on the substrate 10 correspondingly.

Refer to FIG. 3, the die 20 is cut from a wafer and provided with a first surface 21 and a second surface 22 opposite to the first surface 21. The first surface 21 is fixed on the second surface 12 of the substrate 10 and a plurality of die pads 23 is disposed on the second surface 22. A range perpendicular to the second surface 22 of the die 20 is defined as a die area 1a.

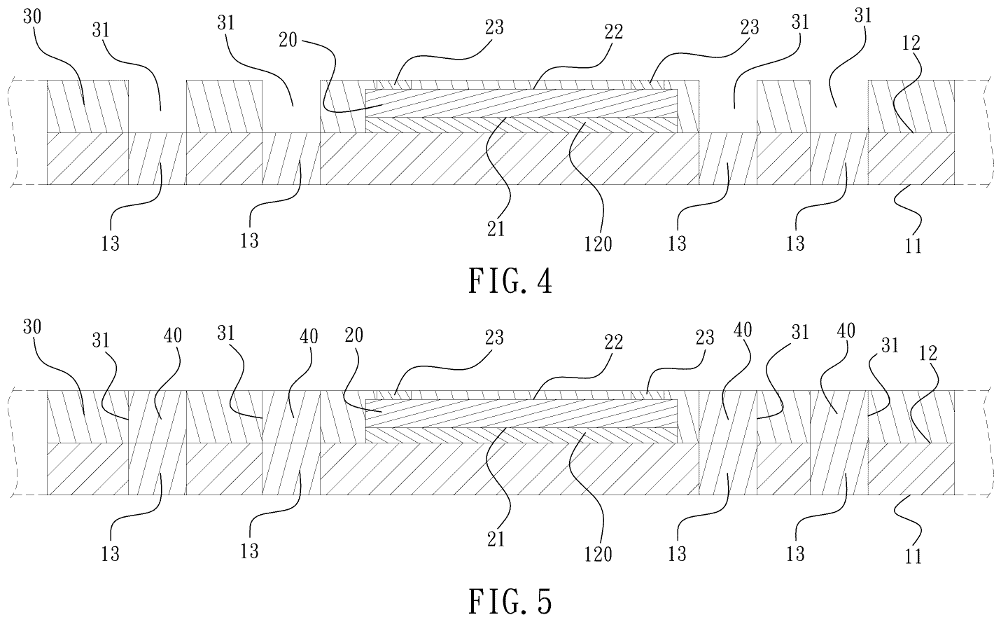

Refer to FIG. 4, the first dielectric layer 30 is arranged at the second surface 12 of the substrate 10 and covering the die 20. The first dielectric layer 30 is provided with at least one insertion hole 31 which is formed by a Through Silicon Via (TSV) process. The respective insertion holes 31 are connected to the first conductive pillars 13 correspondingly.

Refer to FIG. 4, the second conductive pillar 40 is formed in each of the insertion holes 31 to be electrically connected to the corresponding first conductive pillar 13 and exposed through the insertion hole 31.

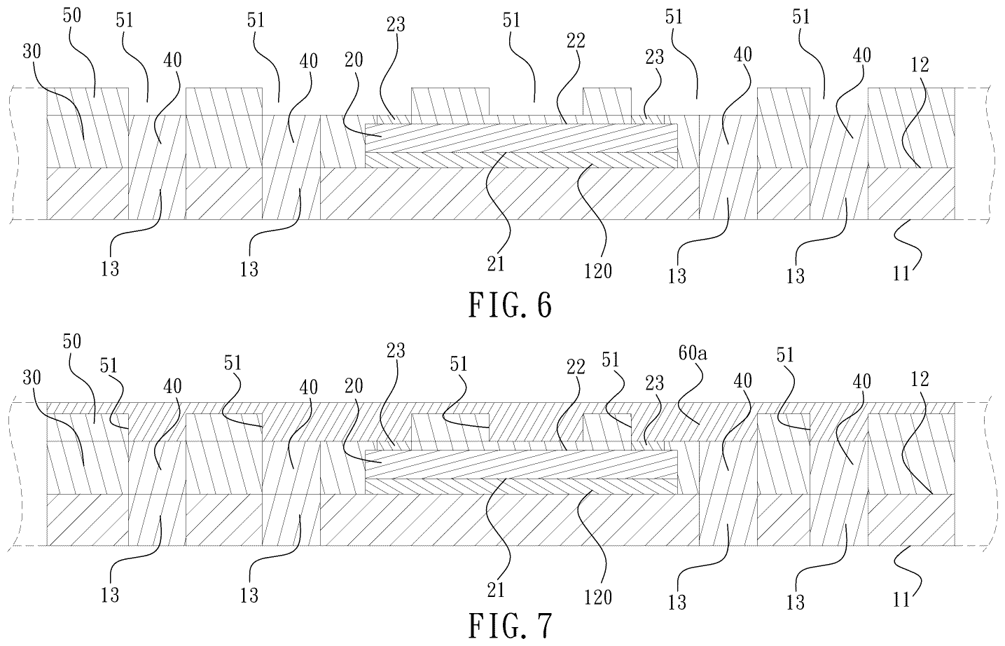

Refer to FIG. 6, the second dielectric layer 50 is disposed over the first dielectric layer 30 and having at least one slot 51 which is extending in a horizontal direction and connected to the corresponding second conductive pillar 40.

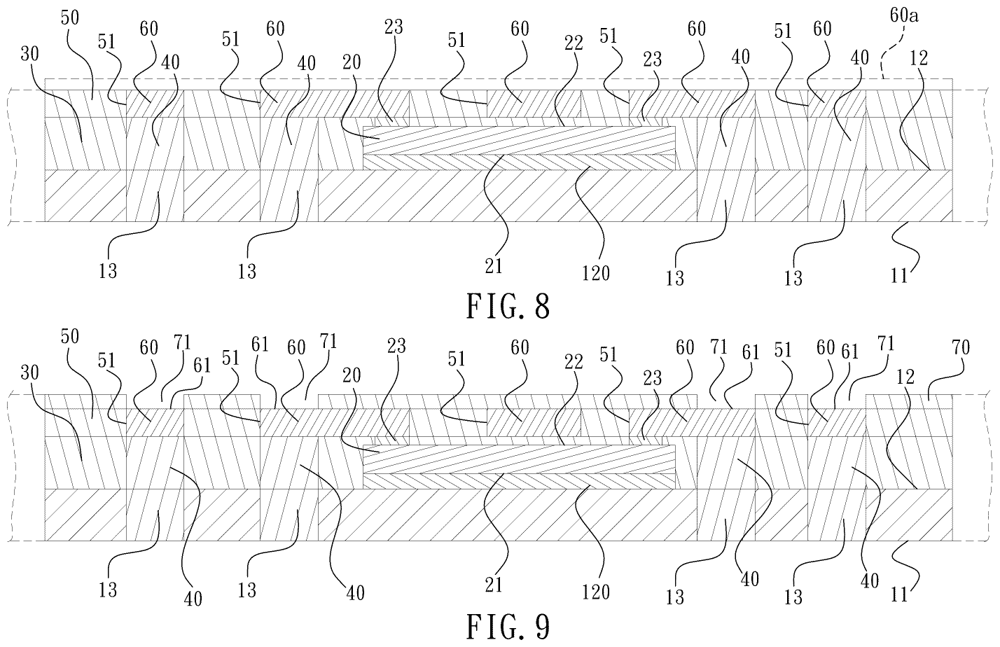

Refer to FIG. 8, the respective first conductive circuits 60 are formed by a metal paste 60a filled into the respective slots 51 correspondingly and electrically connected to the second conductive pillars 40.

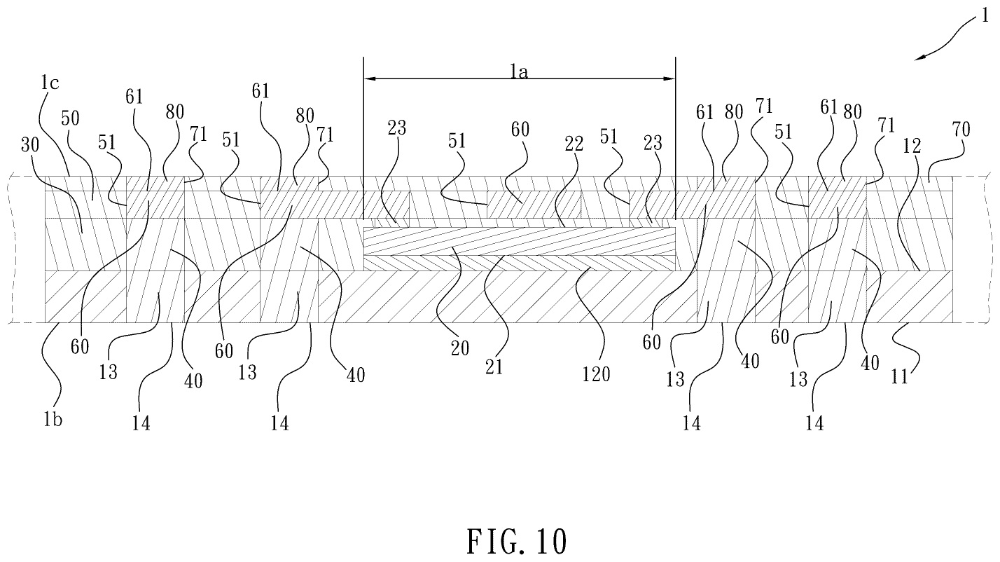

Refer to FIG. 9, the third dielectric layer 70 is disposed over the second dielectric layer 50 and the first conductive circuits 60. The third dielectric layer 70 is provided with at least one first opening 71. Refer to FIG. 10, the respective first conductive circuits 60 are exposed through the respective first openings 71 and forming a first bonding pad 61 in each of the first openings 71. In the FIG. 10, the FOWLP unit 1 includes four first bonding pads 61, but the number of the first bonding pads 61 is not limited.

Refer to FIG. 10, the metal protective layers 80 are formed in the first openings 71 correspondingly and electrically connected to the respective first conductive circuits 60 for increasing structural strength and protecting the respective first conductive circuits 60.

Refer to FIG. 10, each of the first conductive pillars 13 is exposed on the first surface 11 of the substrate 10 and forming a second bonding pad 14 on the first surface 11 of the substrate 10. In the FIG. 10, the FOWLP unit 1 includes four second bonding pads 14, but the number of the second bonding pads 14 is not limited.

Refer to FIG. 10, the die 20 is electrically connected to the outside through the die pads 23 of the die 20, the first conductive circuits 60, the second conductive pillars 40, the first conductive pillars 13, and the second bonding pads 14 located at the substrate 10 in turn.

Refer to FIG. 10, the die 20 is electrically connected to the outside through the die pads 23 of the die 20, the first conductive circuits 60, the metal protective layers 80, and the first bonding pads 61 around the die area 1a on the second surface 22 of the die 20 in turn. Thereby the FOWLP unit 1 is formed.

Refer to FIG. 10, the FOWLP unit 1 further includes a first surface 1b and a second surface 1c. The respective second bonding pads 14 of the substrate 10 are located on the first surface 1b of the FOWLP unit 1. The first bonding pads 61 in the first openings 71 of the FOWLP unit 1 are located at the second surface 1c of the FOWLP unit 1. The second bonding pads 14 on the first surface 1b of the FOWLP unit 1 and the first bonding pads 61 on the second surface 1c of the FOWLP unit 1 have the same arrangement (layout).

A method of manufacturing the FOWLP unit 1 includes the following steps.

Step S1: providing a substrate 10, as shown in FIG. 2. The substrate 10 consists of a first surface 11, a second surface 12 opposite to the first surface 11, and a plurality of first conductive pillars 13 penetrating the first surface 11 and the second surface 12. The first conductive pillars 13 are exposed on the first surface 11 of the substrate 10 to form second bonding pads 14 on the first surface 11 of the substrate 10, as shown in FIG. 10.

Step S2: arranging a plurality of dies 20 cut from at least one wafer at the substrate 10 with an interval between the two adjacent dies 20, as shown in FIG. 3. Each of the dies 20 is provided with a first surface 21 fixed on the second surface 12 of the substrate, a second surface 22 opposite to the first surface 21, and a plurality of die pads 23 disposed on the second surface 21. A range perpendicular to the second surface 22 of the die 20 is defined as a die area 1a.

Step S3: paving a first dielectric layer 30 over the second surface 12 of the substrate 10 and the dies 20 and the first dielectric layer 30 covering the respective dies 20. Then forming a plurality of insertion holes 31 on the first dielectric layer 30 and penetrating the first dielectric layer 30, as shown in FIG. 4. Later forming a second conductive pillar 40 in each of the insertion holes 31, as shown in FIG. 5.

Step S4: producing a plurality of first conductive circuits 60 on the second surface 22 of the die 20 by filling a metal paste into slots and grinding the metal paste. First paving a second dielectric layer 50 over the second surface 12 of the substrate 10. Then forming a plurality of slots 51 horizontally on the first dielectric layer 50 and exposing the second conductive pillars 40 through the slots 51, as shown in FIG. 6. Next filling a metal paste 60a into the slots 51 and a level of the metal paste 60a is higher than a surface of the second dielectric layer 50, as shown in FIG. 7. Lastly grinding the metal paste 60a with the level higher than a surface of the second dielectric layer 50 to make a surface of the metal paste 60a flush with the surface of the second dielectric layer 50 and form a plurality of the first conductive circuits 60, as shown in FIG. 8.

Step S5: paving a third dielectric layer 70 over the second dielectric layer 50 and forming a plurality of openings 71 horizontally on the third dielectric layer 70 so that the first conductive circuits 60 are exposed through the first openings 71. Lastly forming a metal protective layer 80 in the respective first openings 71. Each of the first conductive circuits 60 forms a first bonding pad 61 in each of the first openings 71, as shown in FIG. 9. The metal protective layers 80 are electrically connected to the first conductive circuits 60.

Step S6: performing cutting to form a plurality of FOWLP units 1.

The process in the step S4 of the method of manufacturing the FOWLP unit 1 can be considered as the key step in production of RDL of the FOWLP unit 1. Since the step S4 is precise and easily-implemented, the manufacturing process is simplified and the FOWLP unit 1 produced is still having a certain degree of compact design under condition that the respective conductive circuits in the RDL have electrical extension in the XY plane and interconnections.

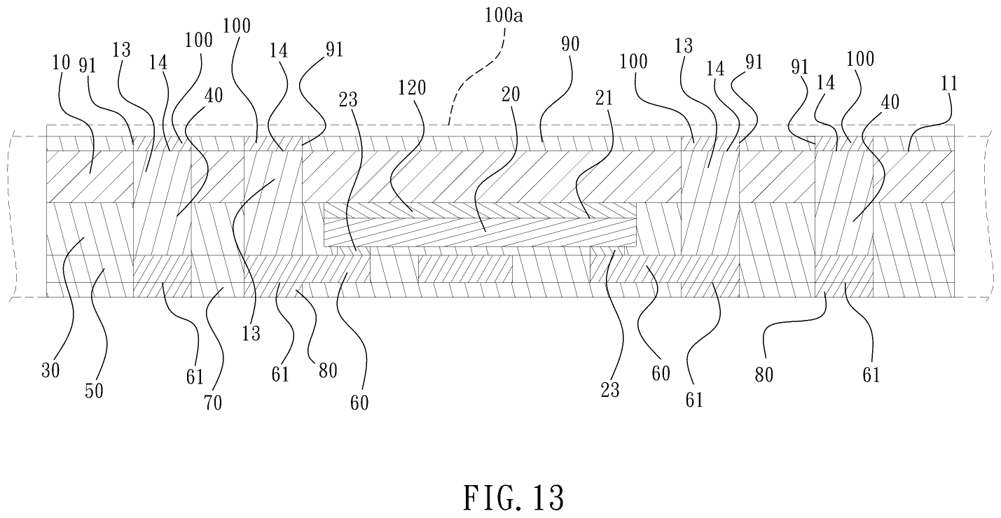

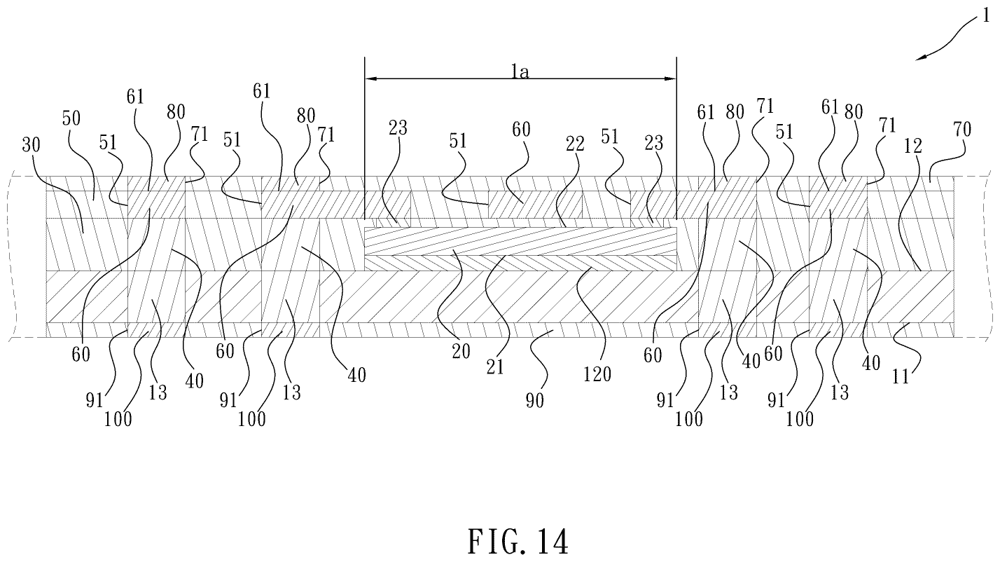

Refer to FIG. 13 and FIG. 14, a fourth dielectric layer 90 and a plurality of second conductive circuits 100 are disposed on the first surface 11 of the substrate 10 by the RDL process. The fourth dielectric layer 90 is provided with at least one second opening 91 extending in a horizontal direction. The second conductive circuits 100 are formed by a metal paste 100a filled in the respective second openings 91 and electrically connected with the second bonding pads 14.

A method of manufacturing the second conductive circuits 100 includes the following steps.

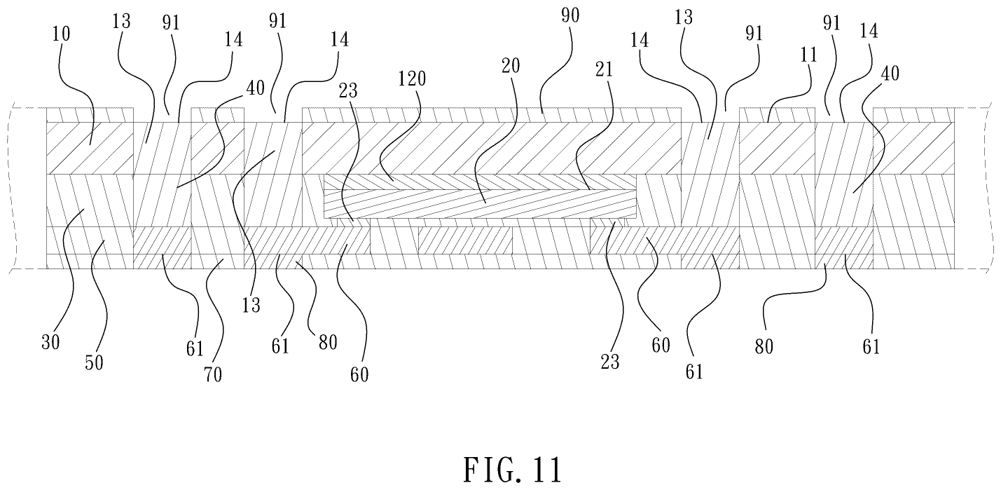

Step S1: refer to FIG. 11, first paving a fourth dielectric layer 90 on the first surface 11 of the substrate 10; then forming a plurality of second openings 91 horizontally on the fourth dielectric layer 90 and allowing the second bonding pads 14 to be exposed through the second openings 91.

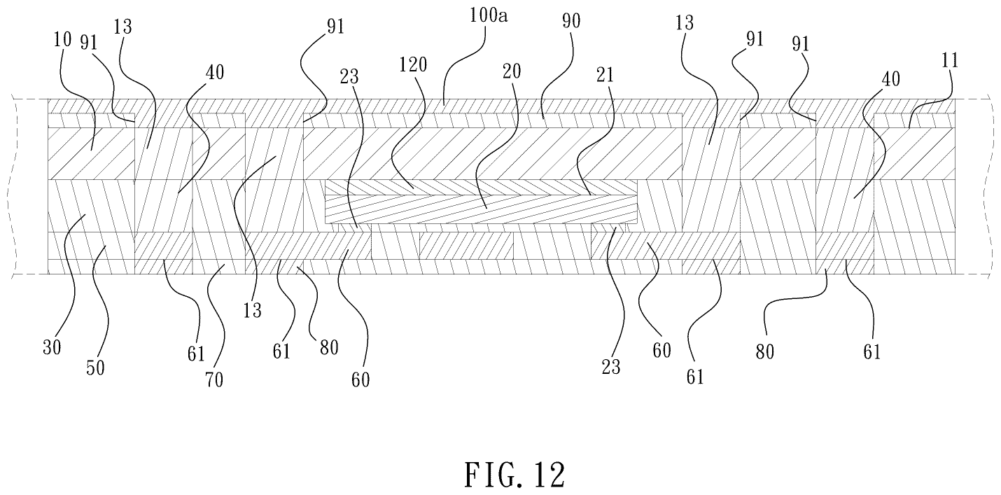

Step S2: refer to FIG. 12, filling a metal paste 100a into the respective second openings 91 and allowing a level of the metal paste 100a higher than a surface of the fourth dielectric layer 90.

Step S3: refer to FIG. 13, grinding the metal paste 100a with the level higher than the surface of the fourth dielectric layer 90 to make a surface of the metal paste 100a flush with the surface of the fourth dielectric layer 90 and form a plurality of second conductive circuits 100.

Refer to FIG. 1, each of the second conductive circuits 100 is provided with a solder ball 110 which is electrically connected to the first bonding pad 61 through the second conductive circuit 100. The FOWLP unit 1 is electrically connected to and arranged at a printed circuit board (PCB) 3 by the solder balls 110, but not limited.

Refer to FIG. 2, the substrate 10 includes, but not limited to, a silicon substrate, a glass substrate, and a ceramic substrate.

Refer to FIG. 8, the metal pastes 60a, 100a used to produce the first and the second conductive circuits 60, 100 include silver paste, nano-scale silver paste, copper paste, and nano-scale copper paste.

Refer to FIG. 1, a thickness of the FOWLP unit 1 is 200 micrometers (um).

Refer to FIG. 3, the first surface 21 of the die 20 is arranged at the substrate 10 by a die attach film (DAF).

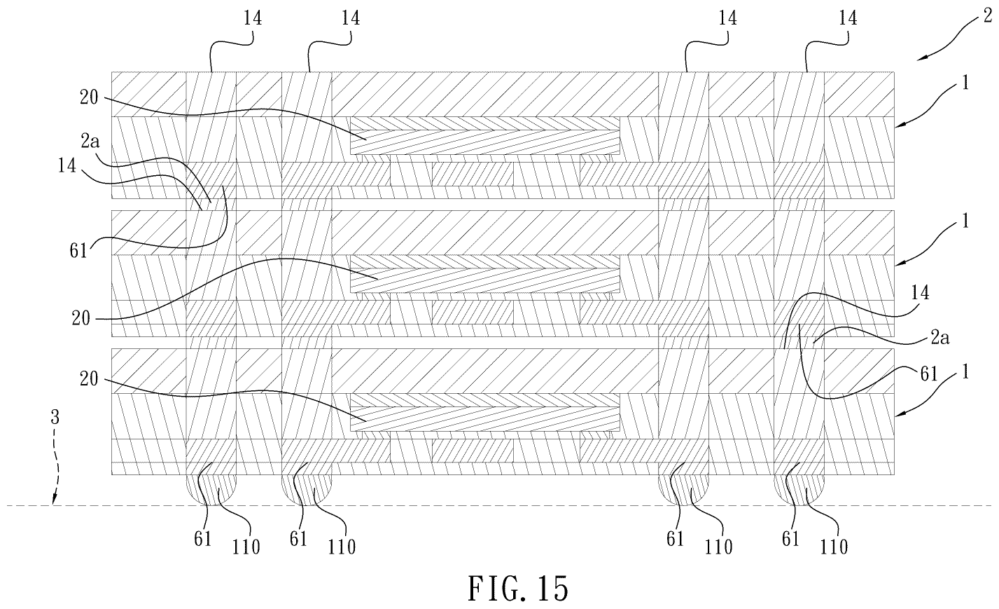

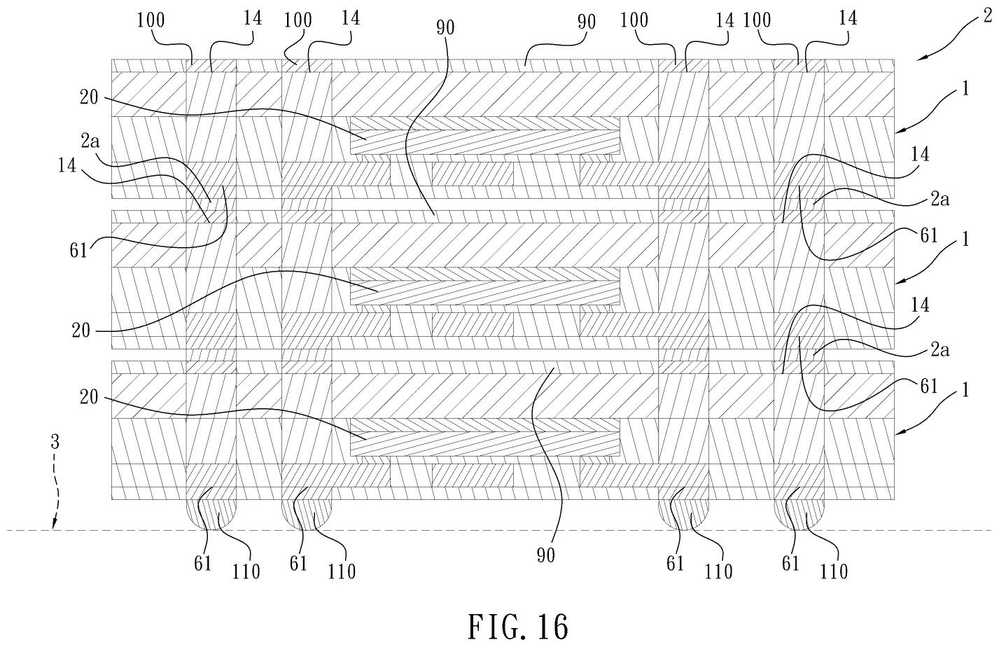

Refer to FIG. 15 and FIG. 16, a plurality of the FOWLP units 1 can be stacked to form a package 2. The package 2 includes at least two FOWLP units 1 and at least one connecting circuit 2a.

The FOWLP units 1 are stacked vertically such as one at an upper position and another at a lower position correspondingly. The second bonding pads 14 of one of the upper FOWLP units 1 are corresponding to the first bonding pads 61 of one of the lower FOWLP units 1 in a one-to-one manner. In the embodiment shown in FIG. 15 and FIG. 16, there are three FOWLP units 1, but the number of the FOWLP units 1 is not limited.

The connecting circuit 2a is arranged between the second bonding pads 14 of one of the upper FOWLP units 1 and the first bonding pads 61 of one of the lower FOWLP units 1 to form an electrical connection. Thus one of the upper FOWLP units 1 and one of the lower FOWLP units 1 are electrically connected by the connecting circuit 2a. The connecting circuit 2a can be, but not limited to, a solder ball.

Refer to FIG. 15 and FIG. 16, the dies 20 of one of the upper FOWLP units 1 and the dies 20 of one of the lower FOWLP units 1 can have the same or different specifications and functions. The package 2 can be electrically connected to and disposed on a printed circuit board 3 by the solder balls 110.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A fan-out wafer level packaging (FOWLP) unit comprising:
a substrate having a first surface, a second surface opposite to the first surface, and a plurality of first conductive pillars penetrating the first surface and the second surface;
at least one die cut from a wafer and provided with a first surface and a second surface opposite to the first surface; the first surface of the die fixed on the second surface of the substrate and a plurality of die pads disposed on the second surface of the die; a range perpendicular to the second surface of the die being defined as a die area;
a first dielectric layer arranged at the second surface of the substrate and covering the die; the first dielectric layer having at least one insertion hole; wherein the insertion hole is connected to the first conductive pillar correspondingly;
at least one second conductive pillar formed in each of the insertion holes to be electrically connected to the first conductive pillar correspondingly and exposed through the insertion hole;
a second dielectric layer disposed over the first dielectric layer and having at least one slot extending in a horizontal direction; wherein the slot is connected to the second conductive pillar correspondingly;
a plurality of first conductive circuits formed by a metal paste filled into the slots and electrically connected to the second conductive pillars;
a third dielectric layer disposed over the second dielectric layer and the first conductive circuits; the third dielectric layer having at least one first opening; the respective first conductive circuits exposed through the respective first openings and forming a first bonding pad in each of the first openings; and
a plurality of metal protective layers formed in the first openings correspondingly and electrically connected to the first conductive circuits;
wherein each of the first conductive pillars is exposed on the first surface of the substrate and forming a second bonding pad on the first surface of the substrate;
wherein the die is electrically connected to the outside through the die pads of the die, the first conductive circuits, the second conductive pillars, the first conductive pillars, and the second bonding pads located at the substrate in turn;
wherein the die is electrically connected to the outside through the die pads of the die, the first conductive circuits, the metal protective layers, and the first bonding pads around the die area on the second surface of the die in turn; thereby the FOWLP unit is formed;
wherein the FOWLP unit further includes a first surface and a second surface; the second bonding pads of the substrate in the FOWLP unit are located on the first surface of the FOWLP unit; wherein the first bonding pads in the first openings of the FOWLP unit are located at the second surface of the FOWLP unit; wherein the second bonding pads on the first surface of the FOWLP unit and the first bonding pads on the second surface of the FOWLP unit have the same arrangement;
wherein a method of manufacturing the FOWLP unit comprising the steps of:
Step S1: providing a substrate having a first surface, a second surface opposite to the first surface, and a plurality of first conductive pillars penetrating the first surface and the second surface and exposed on the first surface of the substrate to form second bonding pads on the first surface of the substrate correspondingly;
Step S2: arranging a plurality of dies cut from at least one wafer at the substrate with an interval between the two adjacent dies; wherein each of the dies is provided with a first surface fixed on the second surface of the substrate, a second surface opposite to the first surface, and a plurality of die pads disposed on the second surface of the die; a range perpendicular to the second surface of the die is defined as a die area;
Step S3: paving a first dielectric layer over the second surface of the substrate and the dies and the first dielectric layer covering the respective dies; then forming a plurality of insertion holes on the first dielectric layer and penetrating the first dielectric layer; later forming a second conductive pillar in each of the insertion holes;
Step S4: producing a plurality of first conductive circuits on the second surface of the die by filling a metal paste into slots and grinding the metal paste; first paving a second dielectric layer over the second surface of the substrate; then forming a plurality of slots horizontally on the first dielectric layer and exposing the second conductive pillars through the slots; next filling a metal paste into the slots and allowing a level of the metal paste higher than a surface of the second dielectric layer; lastly grinding the metal paste with the level higher than a surface of the second dielectric layer to make a surface of the metal paste flush with the surface of the second dielectric layer and form a plurality of the first conductive circuits;
Step S5: paving a third dielectric layer over the second dielectric layer and forming a plurality of openings horizontally on the third dielectric layer so that the first conductive circuits are exposed through the first openings; lastly forming a metal protective layer in the respective first openings; wherein each of the first conductive circuits forms a first bonding pad in each of the first openings; wherein the metal protective layers are electrically connected to the first conductive circuits correspondingly; and
Step S6: performing cutting to form a plurality of FOWLP units.

2. The FOWLP unit as claimed in claim 1, wherein a fourth dielectric layer and a plurality of second conductive circuits are disposed on the first surface of the substrate by a redistribution layer (RDL) process; wherein the fourth dielectric layer is provided with at least one second opening extending in a horizontal direction; the second conductive circuits are formed by a metal paste filled in the second openings; wherein the second conductive circuits are electrically connected with the second bonding pads;
wherein a method of manufacturing the second conductive circuits comprising the steps of:
Step S1: first paving a fourth dielectric layer on the first surface of the substrate; then forming a plurality of second openings horizontally on the fourth dielectric layer and allowing the second bonding pads to be exposed through the second openings;
Step S2: filling a metal paste into the second openings and allowing a level of the metal paste higher than a surface of the fourth dielectric layer; and
Step S3: grinding the metal paste with the level higher than the surface of the fourth dielectric layer to make a surface of the metal paste flush with the surface of the fourth dielectric layer and form a plurality of the second conductive circuits.

3. The FOWLP unit as claimed in claim 2, wherein each of the second conductive circuits is provided with a solder ball which is electrically connected to the first bonding pad through the second conductive circuit.

4. The FOWLP unit as claimed in claim 1, wherein the substrate includes a silicon substrate, a glass substrate, and a ceramic substrate; wherein the metal paste used for producing the first conductive circuits includes silver paste, nano-scale silver paste, copper paste, and nano-scale copper paste.

5. The FOWLP unit as claimed in claim 1, wherein a thickness of the FOWLP unit is 200 micrometers (um).

6. The FOWLP unit as claimed in claim 2, wherein the metal paste used for producing the second conductive circuits includes silver paste, nano-scale silver paste, copper paste, and nano-scale copper paste.

7. The FOWLP unit as claimed in claim 1, wherein the first surface of the die is arranged at the substrate by a die attach film (DAF).

8. A package formed by stacking of a plurality of FOWLP units comprising:
at least two FOWLP units each of which is as claimed in claim 1; the FOWLP units are stacked at an upper position and a lower position and correspondingly to each other; wherein the second bonding pads of one of the FOWLP units at the upper position are corresponding to the first bonding pads of one of the FOWLP units at the lower position in a one-to-one manner; and
at least one connecting circuit arranged between one of the FOWLP units at the upper position and one of the FOWLP units at the lower position; the connecting circuit is electrically connected with the second bonding pad of the one of the FOWLP units at the upper position and the first bonding pad of the one of the FOWLP units at the lower position to form an electrical connection between the one of the FOWLP units at the upper position and the one of the FOWLP units at the lower position.

9. The package as claimed in claim 8, wherein the die of the one of the FOWLP units at the upper position and the die of the one of the FOWLP units at the lower position have the same or different specifications and functions.

10. The package as claimed in claim 8, wherein the connecting circuit is a solder ball.
